(19) United States
(12) Patent Application Publication
(10) Pub. No.: US 2023/0317568 A1
(43) Pub. Date: Oct. 5, 2023

(54) ISOLATION PACKAGE WITH HIGH THERMAL CONDUCTIVITY

(71) Applicant: Texas Instruments Incorporated, Dallas, TX (US)

(72) Inventors: Daiki Komatsu, Beppu (JP); Anindya Poddar, Sunnyvale, CA (US); Hau Nguyen, San Jose, CA (US)

(21) Appl. No.: 17/710,077

(22) Filed: Mar. 31, 2022

(51) Int. Cl. H01L 23/495; H01L 23/00; H01L 23/31; H01L 21/56; H01L 21/78

(52) U.S. Cl. CPC H01L 23/49513; H01L 24/32; H01L 23/3107; H01L 24/29; H01L 24/48; H01L 24/73; H01L 24/92; H01L 21/56; H01L 21/78; H01L 2224/32245; H01L 2224/2919; H01L 2224/48221; H01L 2224/73265; H01L 2224/92247

(57) ABSTRACT

An integrated circuit package includes a die attach pad (DAP) having a top surface and a layer of insulating material applied to the top surface of the DAP. A silicon-on-insulator (SOI) device is mounted on the insulating material using a die attach paste or film. A plurality of leads are coupled to the SOI device using bond wires. A mold compound covers at least a portion of the DAP and the SOI device. The insulating material may be polyimide or polyamide-imide that has been inkjet printed or screen printed on the DAP. The insulating material may be a parylene material that is applied to the top surface of the DAP using chemical vapor deposition. The insulating material has a thickness of 1-25 um and has a breakdown voltage of approximately 250V/um.

### BACKGROUND

Semiconductor packages include a semiconductor die embedded in a mold compound. Electrical connections within the mold compound are formed between terminals of the semiconductor die and leads of the package. The leads are part of a lead frame to which the semiconductor die is attached. Thermal conduction and heat dissipation is of great need in semiconductor devices due to the presence of the thermal energy from self-heating semiconductor components. Galvanic isolation is also important in semiconductor packages to separate electrical circuits and to eliminate stray currents.

### SUMMARY

An example integrated circuit package includes a die attach pad (DAP) having a top surface and a layer of insulating material applied to the top surface of the DAP. A silicon-on-insulator (SOI) device is mounted on the insulating material using a die attach paste or film. A plurality of leads are coupled to the SOI device using bond wires. A mold compound covers at least a portion of the DAP and the SOI device. The insulating material may be polyimide or polyamide-imide that has been inkjet printed or screen printed on the DAP. The insulating material may be a parylene material that is applied to the top surface of the DAP using chemical vapor deposition. The insulating material has a thickness of 1-25 um and has a breakdown voltage of approximately 250V/um.

An example method for manufacturing a semiconductor package includes providing a lead frame having a plurality of die attach pads (DAP), wherein each die attach pad has a top surface with a layer of insulation material; adhering a silicon-on-insulator (SOI) device to each DAP using a die attach material; attaching wire bonds from contacts on each SOI device to leads on the lead frame; and covering at least a portion of the SOI devices, DAPs, insulation layer, wire bonds, and leads with a mold compound.

### BRIEF DESCRIPTION OF THE DRAWINGS

Having thus described the invention in general terms, reference will now be made to the accompanying drawings, wherein:

FIG. 1 is a side elevation, cross section view of an example semiconductor isolation package.

FIGS. 2A-E schematically illustrate an example process of manufacturing a lead frame with a thin isolation layer using screen printing, inkjet printing, or spray coating.

FIGS. 3A-G schematically illustrate an example process of manufacturing a lead frame with a thin isolation layer using selective deposition.

FIGS. 4A-C schematically illustrate an example process for assembling an isolation package using a lead frame with a thin isolation layer.

FIG. 5 shows a perspective view of an example semiconductor device package, such as an isolation package, with high galvanic isolation and high thermal conductivity.

FIG. 6 is a flowchart illustrating an example process for manufacturing a semiconductor package.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In the drawings, like reference numerals refer to like elements throughout, and the various features are not necessarily drawn to scale. Corresponding numerals and symbols in the different figures generally refer to corresponding parts, unless otherwise indicated. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor device” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a “semiconductor die.”

The term “integrated circuit package” is used herein. An integrated circuit package has at least one semiconductor device electrically coupled to terminals and has a package body that protects and covers the semiconductor device. In some arrangements, multiple semiconductor devices can be packaged together. For example, a power field effect transistor (FET) semiconductor device and a second semiconductor device (such as a gate driver die or a controller die) can be packaged together to from a single packaged electronic device. Additional components such as passives can be included in the packaged electronic device. The semiconductor device is mounted with a package substrate that provides conductive leads. A portion of the conductive leads form the terminals for the packaged device. In wire bonded integrated circuit packages, bond wires couple conductive leads of a package substrate to bond pads on the semiconductor device. The integrated circuit package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the integrated circuit package. The integrated circuit package may also be referred to herein as a “semiconductor package” or a “sensor package.”

A package substrate is a substrate arranged to receive a semiconductor die and to support the semiconductor die in a completed semiconductor device package. Package substrates useful with the arrangements include conductive lead frames, which can be formed from copper, aluminum, stainless steel, steel, and alloys such as Alloy 42 and copper alloys. The lead frames can include a die pad with a die side surface for mounting a semiconductor die, and conductive leads arranged near and spaced from the die pad for coupling to bond pads on the semiconductor die using wire bonds, ribbon bonds, or other conductors. In example arrangements, a heat slug is attached to the package substrate, and the heat slug has a die mounting area for mounting semiconductor devices. The lead frames can be provided in strips or arrays. The conductive lead frames can be provided as a panel with strips or arrays of unit device portions in rows and columns. Semiconductor devices can be placed on respective unit device portions within the strips or arrays. A semiconductor device can be placed on a die mount area for each packaged semiconductor device. Die attach or die adhesive can be used to mount the semiconductor devices. In wire bonded packages, bond wires can couple bond pads on the semiconductor devices to the leads of the lead frames. The lead frames may have plated portions in areas designated for wire bonding, for example silver, nickel, gold, or palladium plating can be used. After the bond wires are in place, a portion of the package substrate, the semiconductor device, and at least a portion of the die pad can be covered with a protective material such as a mold compound. More than one semiconductor device can be mounted to a package substrate for each unit.

The term “die attach pad” is used herein. A die attach pad is portion of a metal lead frame that is adapted for mounting a semiconductor device or semiconductor die. The semiconductor device may be mounted on the die attach pad by a layer of die attachment material that electrically and physically connects the semiconductor device to the lead frame.

The term “insulating material” is used herein. An insulating material may be used to separate conductive elements in such a way to prevent the flow of DC and undesirable AC signals or currents. Typically, insulating materials have a low dielectric constant and high dielectric strength.

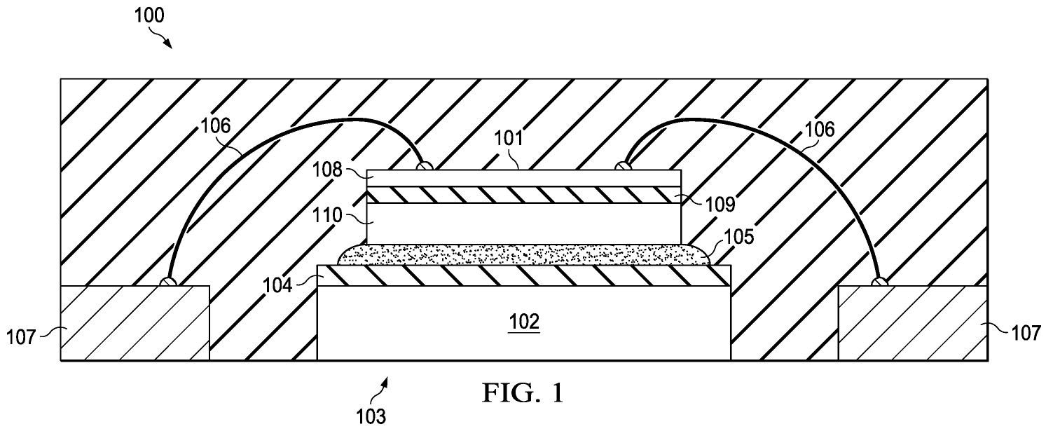

FIG. 1 is a side elevation, cross section view of an example semiconductor isolation package 100. Isolation package 100 provides high thermal conductivity as well as high voltage isolation with minimal added cost during manufacture. Isolation package 100 includes a silicon-on-insulator (SOI) device 101 that is mounted on a die attach pad (DAP) portion 102 of a lead frame 103. A thin layer of an insulating material 104 is applied to a top surface of the DAP portion 102. The SOI device 101 is mounted to the insulation material 104 using a conductive die attach 105. A plurality of bond wires 106 are coupled between bond pads on SOI device 101 and leads 107 on lead frame 103. The SOI device 101 has a thin layer of silicon 108 on top of a buried oxide layer 109. The buried oxide layer 109 isolates the thin silicon layer 108 from the silicon substrate 110. Active circuitry, such as transistors, are built on the thin silicon layer 108. The buried oxide layer may be silicon dioxide (SiO2), for example, to provide insulation in microelectronic devices. The full dielectric isolation of devices on the thin silicon layer 108 reduces parasitic capacitance and provides galvanic isolation to block DC and unwanted AC currents.

In an example manufacturing process, the thin layer of insulation 104 may be applied to lead frame 103 by a lead frame supplier. Insulation layer 104 may be applied to lead frame panel or strip using processes such as offset gravure printing, inkjet printing, screen printing, spray coating, or selective deposition. By applying the insulation layer 104 at the lead frame supplier, there is no additional processing required at package assembly. This design is compatible with existing assembly process flow with minimal process development and no new tool would be required.

Efficient heat management is essential to dissipate excessive heat in improving the efficiency and reliability of electronic devices, such as isolation package 100. In some examples, insulation layer 104 comprises a high insulation material such as parylene, polyimide, or polyamide-imide. An example insulation material provides a breakdown voltage of approximately 250V/um. Using such a material, an isolation layer 104 having a thickness of 1-25 um will provide approximately 1000 volts of isolation. An insulation layer having a thickness of 1-25 um provides a thermal path from the SOI device 101 to the lead frame 103. Accordingly, isolation package 100 can meet device voltage isolation requirements with minimal thermal impact. Applying a thin insulation layer of 1-25 um allows the package footprint and size to be maintained after the insulation material is added. Insulation layers greater than 25 um may require additional processes and tooling during package assembly.

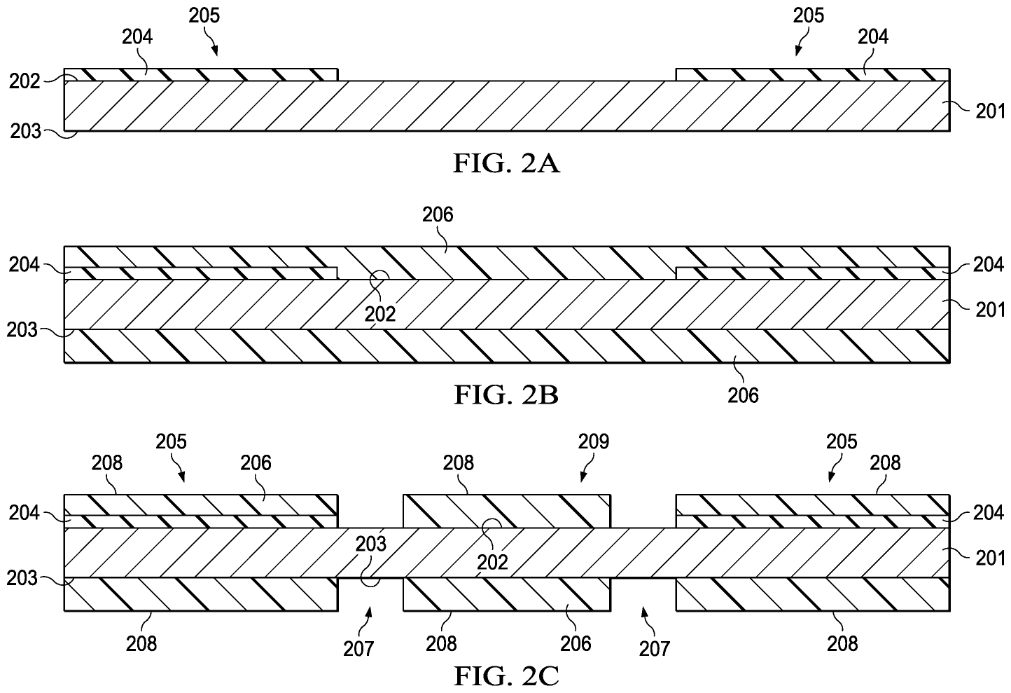

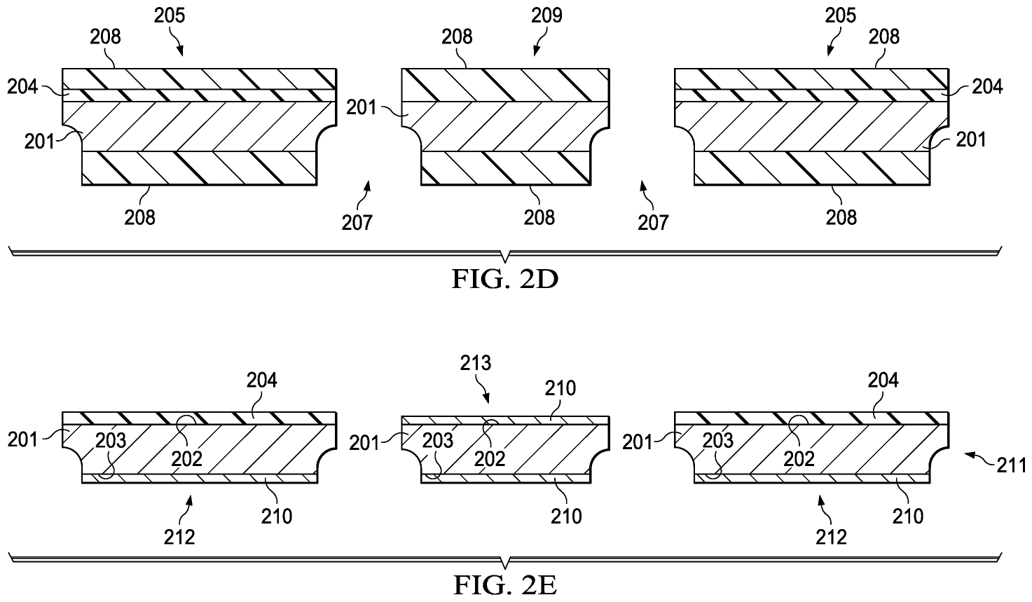

FIGS. 2A-E schematically illustrate an example process of manufacturing a lead frame with a thin isolation layer using screen printing, inkjet printing, or spray coating. In FIG. 2A, a lead frame raw material 201 is provided. Material 201 may be a metal that is generally used in lead frame manufacturing, such as steel, copper (Cu), Cu alloy, nickel (Ni), and Ni alloy. The lead frame material 201 has a top surface 202 and a bottom surface 203. An insulation material 204 is applied to one or more selected areas 205 on the top surface 202 of material 201. Insulation material 204 may be applied by screen printing, inkjet printing, or spray coating on areas 205. When applied by printing, the insulation material may be an ink residue. In some examples, insulation material 204 may be polyimide or polyamide-imide. Polyimide and polyamide-imide materials have relatively high dielectric constants (K) and excellent dielectric withstanding voltages on the order of 250V/um (polyamide-imide) to 470V/um (polyimide). The thermal conductivity of polyimide and polyamide-imide allow them to transfer heat while providing galvanic isolation. For example, polyimide may have a thermal conductivity of approximately 0.12-0.18 W/(mK) and polyamide-imide may have a thermal conductivity on the order of 0.36 W/(mK). Polyimide and polyamide-imide are superior to other materials as an insulation layer in view of their high breakdown voltage of approximately 250V/um. A thin layer of polyimide or polyamide-imide can withstand high voltages with minimal impact on thermal performance. Polyimide and polyamide-imide is also ideal as an insulation material because a thin layer may be applied by the lead frame supplier so that additional processes or tooling are not required at the package assembly site.

In FIG. 2B, a photoresist material 206, such as a dry film resist (DFR), is laminated on the top surface 202 and bottom surface 203 of the lead frame material 201. The photoresist 206 lamination also covers areas of insulation material 204 on the top surface 202.

In FIG. 2C, the photoresist material 206 has been irradiated, such as with a visible light laser, in the form of a desired lead frame pattern image. The photoresist material 206 is then subjected to a developer that selectively dissolves any non-irradiated portion of the negative tone photoresist material or irradiated portion of the positive tone photoresist material 206 thereby exposing some areas 207 of the lead frame material 201. As a result, only portions 208 of the photoresist material 206 remain intact to form a mask corresponding to the desired lead frame pattern. In one example, areas 205 remains masked to form DAP portions on which semiconductor devices may be mounted, and area 209 remains masked to form lead frame leads that may function as external connections.

In FIG. 2D, the masked lead frame material 201 is then subjected to a wet or dry etching process. The areas 207 of the lead frame material 201 not covered by the mask are etched away. Those areas of the lead frame material 201 covered by the mask portions 208 are unetched and remain after the etching process.

In FIG. 2E, the mask portions 208 are removed such as by using plasma or wet chemical process with strong base solution that would not damage the unetched insulation layers 204 and unetched portions of the lead frame material 201. After removing the mask 208, one or more layers of pre-plated frame (PPF) material 210 may be plated on the top surface 202 and bottom surface 203 of the lead frame material 201 that is no covered by insulation layer 204. In some examples, the PPF material 210 may include multiple layers of material plated onto the lead frame 201, such as a three-layer plating scheme comprising nickel (Ni), palladium (Pd) and gold (Au). The PPF material may be selectively electroplated onto certain areas of the lead frame surface by using a mechanical mask or a photo-resist mask. The final product is a lead frame strip 211 that may be provided by a lead frame fabricator to another manufacturer for assembly of the isolation package. Lead frame strip 211 comprises one or more DAP portions 212 having thin insulation layers 204 and one or more lead portion 213.

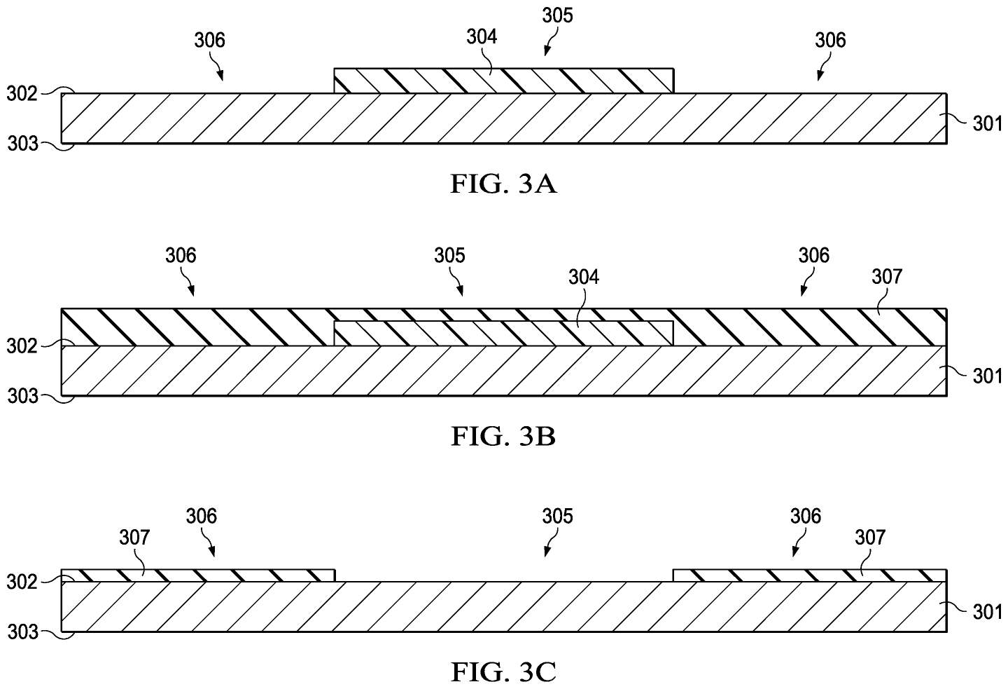

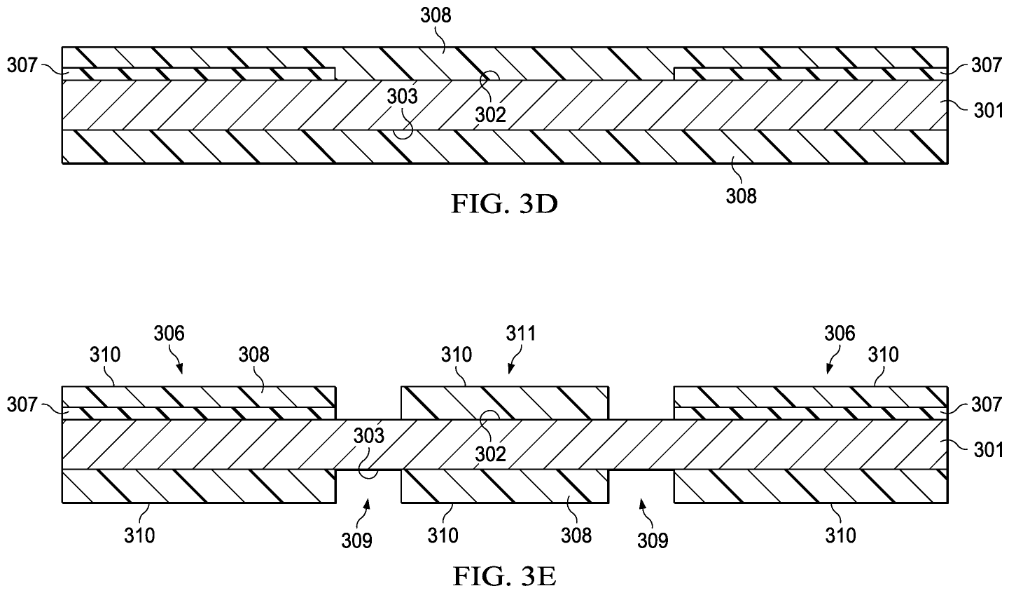

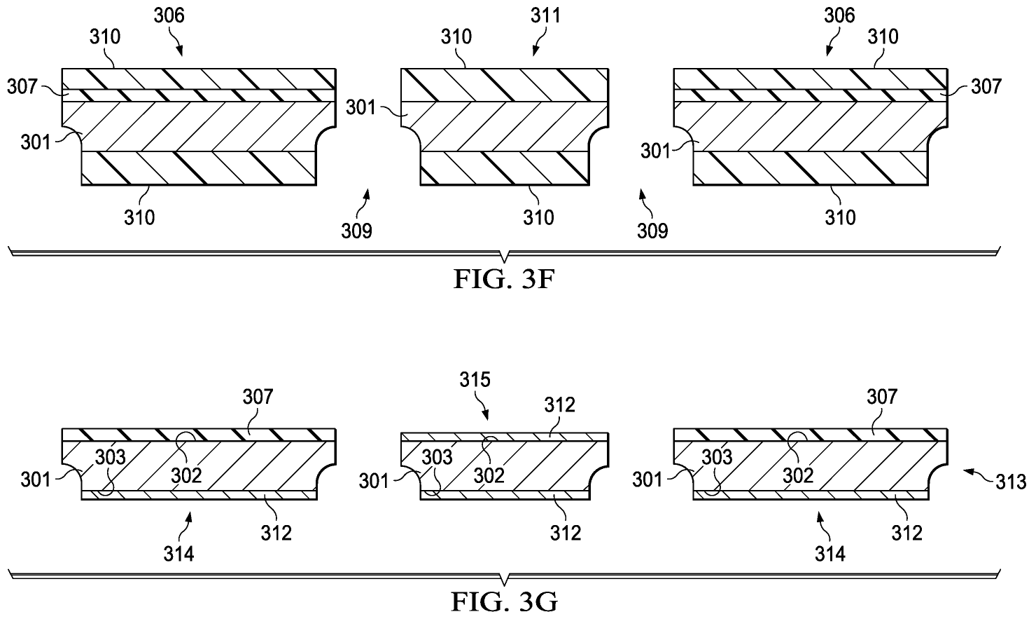

FIGS. 3A-G schematically illustrate an example process of manufacturing a lead frame with a thin isolation layer using selective deposition. In FIG. 3A, a lead frame raw material 301 is provided. As described above, material 301 may be a metal that is generally used in lead frame manufacturing, such as steel, copper (Cu), Cu alloy, nickel (Ni), and Ni alloy. The lead frame material 301 has a top surface 302 and a bottom surface 303. A photoresist material 304, such as a dry film resist (DFR), is applied to a region 305 the top surface 302 of the lead frame material 301. The photoresist material 304 may be applied by lamination or spray coat in some examples. The photoresist material 304 leaves some selected regions 306 exposed on the top surface 302.

In FIG. 3B, an insulation material 307 is applied to areas 305 and 306 on the top surface 302 of material 301. In some examples, insulation material 307 may be parylene. The parylene insulation material 307 may be applied by chemical vapor deposition (CVD) or other vacuum deposition method. Parylenes can be formed in extremely thin layers. The breakdown DC voltages of parylene films are a function of polymer thickness. The breakdown voltage of parylene C is generally superior to parylene N for films under 5 micrometers. Both parylene C and parylene N are materials with high dielectric constants (K) and excellent dielectric withstanding voltages on the order of 250V/um. The thermal conductivity of parylenes allow them to transfer heat while providing galvanic isolation. For example, polyimide may have a thermal conductivity of approximately 0.084 W/(mK) (parylene C) or 0.13 W/(mK) (parylene N). Parylene is superior to other materials as an insulation layer in view of its high breakdown voltage of approximately 250V/um. A thin layer of parylene can withstand high voltages with minimal impact on thermal performance. Parylene is also ideal as an insulation material because a thin layer may be applied by the lead frame supplier so that additional processes or tooling are not required at the package assembly site.

In FIG. 3C, after removing the insulation material 307 from area 305 using laser cutting and peeling off steps, the photoresist material 304 is then subjected to a developer and dissolved thereby exposing top surface 302 in area 305 of the lead frame material 301 while leaving the remaining insulation layer 307 intact in regions 306.

In FIG. 3D, a photoresist material 308, such as a dry film resist (DFR), is laminated on the top surface 302 and bottom surface 303 of the lead frame material 301. The photoresist 308 lamination also covers areas of insulation material 307 on the top surface 302.

In FIG. 3E, the photoresist material 308 has been irradiated, such as with a visible light laser, in the form of a desired lead frame pattern image. The photoresist material 308 is then subjected to a developer that selectively dissolves any non-irradiated portion of the negative tone photoresist material or irradiated portion of the positive tone photoresist material 308 thereby exposing some areas 309 of the lead frame material 301. As a result, only portions 310 of the photoresist material 306 remain intact to form a mask corresponding to the desired lead frame pattern. In one example, areas 306 remain masked to form DAP portions on which semiconductor devices may be mounted, and area 311 remains masked to form lead frame leads that may function as external connections.

In FIG. 3F, the masked lead frame material 301 is then subjected to a wet or dry etching process. The areas 309 of the lead frame material 301 not covered by the mask are etched away and removed. Those areas of the lead frame material 301 covered by the mask portions 310 are unetched and remain after the etching process.

In FIG. 3G, the mask portions 310 are removed such as by using plasma or wet chemical process with strong base solution that would not damage the unetched insulation layers 307 and unetched portions of the lead frame material 301. After removing the mask 310, one or more layers of pre-plated frame (PPF) material 312 may be plated on the top surface 302 and bottom surface 303 of the lead frame material 301 that is no covered by insulation layer 307. In some examples, the PPF material 312 may include multiple layers of material plated onto the lead frame 301, such as a three-layer plating scheme comprising nickel (Ni), palladium (Pd) and gold (Au). The PPF material may be selectively electroplated onto certain areas of the lead frame surface by using a mechanical mask or a photo-resist mask. The final product is a lead frame strip 313 that may be provided by a lead frame fabricator to another manufacturer for assembly of the isolation package. Lead frame strip 313 comprises one or more DAP portions 314 having thin insulation layers 307 and one or more lead portion 315.

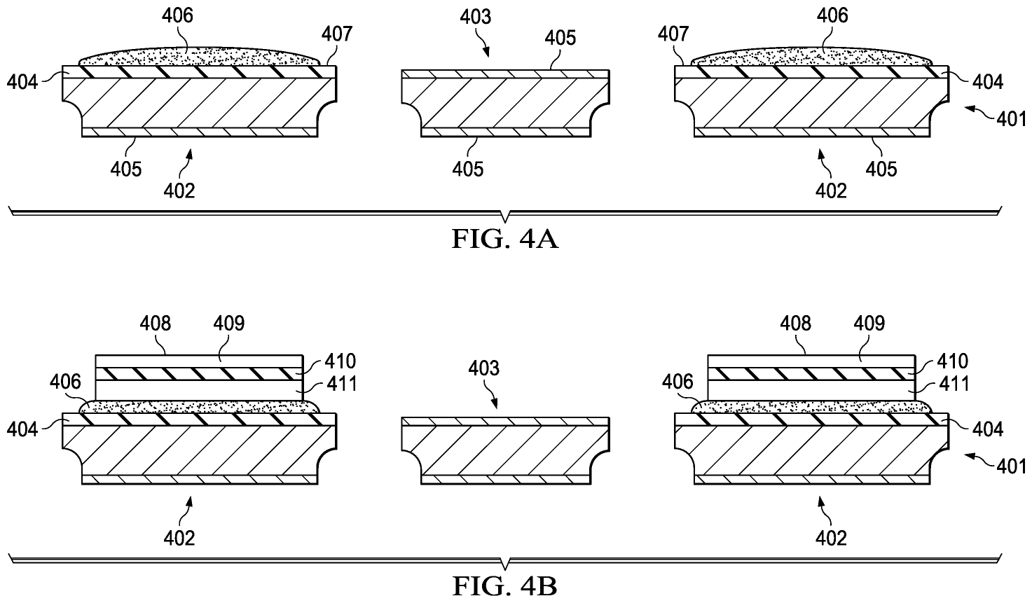

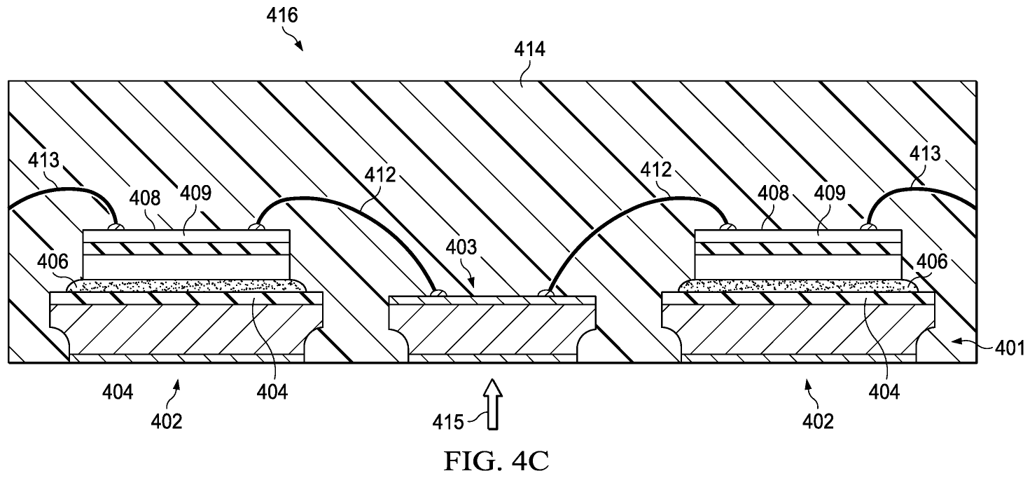

FIGS. 4A-C schematically illustrate an example process for assembling an isolation package using a lead frame with a thin isolation layer. FIG. 4A depicts a portion of a lead frame strip 401 that has a plurality of DAP regions 402 and a plurality of lead regions 403. To simplify the figure, only two DAP regions 402 and only one lead regions 403 are shown; however, it will be understood that numerous other DAP regions 402 and lead regions 403 may be included on the lead frame strip 401. The lead frame strip 401 may be manufactured using example processes illustrated in FIGS. 2A-E or FIGS. 3A-G, such as lead frames 211 or 313.

The DAP regions 402 on lead frame strip 401 have an insulation layer 404 applied to a top surface and a PPF material 405 applied to a bottom surface. In some examples, the insulation layer 404 comprises polyimide, polyamide-imide, or parylene. The lead regions 403 have the PPF material 405 applied to both the top and bottom surfaces. A die attachment film or a die attach paste 406 is placed on a top surface 407 of the insulation layer 404. In some examples, the die attach paste 406 has a high thermal conductivity. The die attach paste 406 is adapted for securing a die thereto. Die attach paste 406 may also be electrically conductive in some examples.

FIG. 4B depicts a SOI devices 408 that have been mounted on DAP portions 402 using die attach paste 406. The SOI devices 408 have a thin layer of silicon 409 on top of a buried oxide layer 410. The buried oxide layer 410 isolates the thin silicon layer 409 from a silicon substrate 411. Active circuitry, such as transistors, are built on the thin silicon layer 409. The SOI devices 408 are attached to the thin insulation layer 404, which provides high thermal conductivity between SOI devices 408 and lead frame 401 while maintaining galvanic isolation between SOI devices 408 and lead frame 401.

FIG. 4C depicts an array of integrated circuit (IC) packages 416. Bond wires 412 that provide electrical connections between the SOI devices 408 and lead portion 403 and bond wires 413 that provide electrical connections between the SOI devices 408 and other components (not shown), such as other lead portions 403 or other semiconductor devices. Bond wires 412, 413 may be gold or copper bond wires in one example. A molding compound 414 has also been applied to at least partially cover the lead frame 401, SOI devices 408, wire bonds 412, 413, and other components.

After the mold compound has been applied, the lead frame 401 and mold compound 414 of the array of IC package 416 may be severed (i.e., “singulated” or “diced”) with a cutting tool, such as a saw or laser. These singulation cuts separate the lead frame strip 401 into separate integrated circuit (IC) packages, wherein each IC package includes a singulated lead frame, at least one semiconductor die or SOI device, and electrical connections (bond wires) between the die and lead frame, and the mold compound which covers at least part of these structures. As used herein, the term lead frame may represent the portions of the lead frame strip 401 remaining within a package after singulation. In one example a device may be singulated along saw streets 415, which cuts through lead portion 403 and mold compound 414 to create separate semiconductor or IC packages with individual SOI devices 408.

Devices that are manufactured in this way have a selectively thin insulator layer that can withstand high voltage applications with minimal thermal performance impact. The thin insulator layer may be applied at the lead frame supplier, which means that there is no additional processing or tooling introduced at the package assembly site. The addition of the thin insulation layer also allows the manufacturer to maintain a desired package footprint.

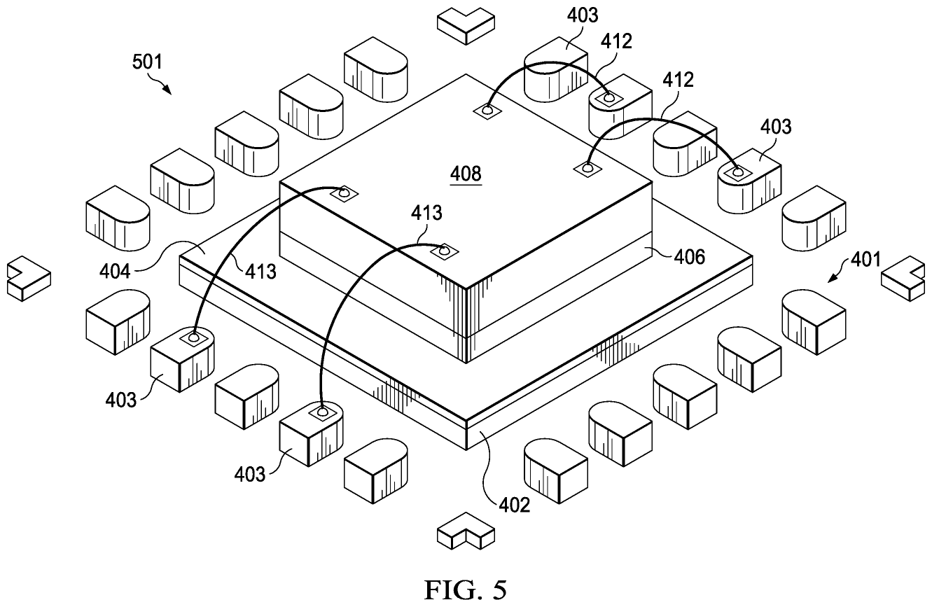

FIG. 5 shows a perspective view of an example semiconductor device package 501, such as an isolation package, with high galvanic isolation and high thermal conductivity. Semiconductor device package 501 may be created using the processes illustrated and described in reference to FIGS. 2A-E, 3A-G, and 4A-C. In one example, an isolation package 501 is an individual IC package that has been singulated from an array of IC packages 416 as illustrated in FIG. 4C. To simplify the drawing, mold compound 414 is not shown in FIG. 5.

The semiconductor device package 501 includes a SOI device 408 that is mounted on a DAP portion 402 using a die attach paste 406. A thin layer of insulating material, such as polyimide, polyamide-imide, or parylene, has been applied to the top of the DAP portion 402. Bond wires 412, 413 provide electrical connections between SOI device 408 and leads 403, which have been cut from a larger lead frame strip 401 during singulation of device 501.

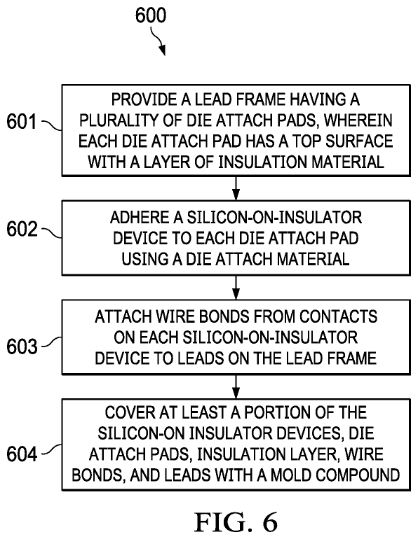

FIG. 6 is a flowchart 600 illustrating an example process for manufacturing a semiconductor package. In step 601, a lead frame having a plurality of die attach pads is provided. Each die attach pad has a top surface with a layer of insulation material. In one example, the insulating material is polyimide or polyamide-imide that has been inkjet printed or screen printed on the die attach pad. In another example, the insulating material is a parylene material that is applied to the top surface of the die attach pad using chemical vapor deposition. The insulating material has a thickness of 1-25 um. The insulating material has a breakdown voltage of approximately 250V/um in one example. The thin insulation layer of 1-25 um allows the package footprint and size to be maintained when the insulation material is added. Insulation layers greater than 25 um may require additional processes and tooling during package assembly.

In step 602, a silicon-on-insulator device is adhered to each die attach pad using a die attach material.

In step 603, wire bonds from contacts on each silicon-on-insulator device are attached to leads on the lead frame.

In step 604, at least a portion of the silicon-on-insulator devices, die attach pad, insulation layer, wire bonds, and leads are covered with a mold compound.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. An integrated circuit package, comprising:
a die attach pad (DAP) having a top surface;
a layer of insulating material on the top surface of the DAP;
a semiconductor device mounted on the insulating material using a die attach paste or film;
a plurality of leads coupled to the semiconductor device using bond wires; and
a mold compound covering at least a portion of the DAP and the semiconductor die.

2. The integrated circuit package of claim 1, wherein the insulating material is polyimide.

3. The integrated circuit package of claim 1, wherein the insulating material is polyamide-imide.

4. The integrated circuit package of claim 1, wherein the insulating material is a parylene material.

5. The integrated circuit package of claim 1, wherein the insulating material has a thickness of 1-25 um.

6. The integrated circuit package of claim 1, wherein the insulating material is an ink residue that is inkjet printed or screen printed on the top surface of the DAP.

7. The integrated circuit package of claim 1, wherein the insulating material is applied to the top surface of the DAP using chemical vapor deposition and lift-off process.

8. The integrated circuit package of claim 1, wherein the insulating material has a breakdown voltage of approximately 250V/um.

9. The integrated circuit package of claim 1, wherein the semiconductor device is a silicon-on-insulator device.

10. An integrated circuit package, comprising:
a die attach pad (DAP) having a top surface;
a layer of insulating material applied to the top surface of the DAP;
a silicon-on-insulator (SOI) device mounted on the insulating material using a die attach paste or film;
a plurality of leads coupled to the SOI device using bond wires; and
a mold compound covering at least a portion of the DAP and the SOI device.

11. The integrated circuit package of claim 10, wherein the insulating material is polyimide or polyamide-imide that has been inkjet printed or screen printed on the DAP.

12. The integrated circuit package of claim 10, wherein the insulating material is a parylene material that is applied to the top surface of the DAP using chemical vapor deposition.

13. The integrated circuit package of claim 10, wherein the insulating material has a thickness of 1-25 um.

14. The integrated circuit package of claim 10, wherein the insulating material has a breakdown voltage of approximately 250V/um.

15. A method of manufacturing a semiconductor package, comprising:
providing a lead frame having a plurality of die attach pads (DAP), wherein each DAP has a top surface with a layer of insulation material;
adhering a silicon-on-insulator (SOI) device to each DAP using a die attach material;
attaching wire bonds from contacts on each SOI device to leads on the lead frame; and
covering at least a portion of the SOI devices, DAPs, insulation layer, wire bonds, and leads with a mold compound.

16. The method of claim 15, wherein the insulating material is polyimide or polyamide-imide that has been inkjet printed or screen printed on the DAP.

17. The method of claim 15, wherein the insulating material is a parylene material that is applied to the top surface of the DAP using chemical vapor deposition.

18. The method of claim 15, wherein the insulating material has a thickness of 1-25 um.

19. The method of claim 15, wherein the insulating material has a breakdown voltage of approximately 250V/um.

20. The method of claim 15, further comprising:
singulating the lead frame, SOI devices, DAPs, insulation layer, wire bonds, and leads into a plurality of integrated circuit packages.
